(19) United States
(12) Patent Application Publication
(10) Pub. No.: US 2026/0297467 A1
(43) Pub. Date: Oct. 1, 2026

(54) CLEANING COMPOSITION AND METHOD OF FORMING PHOTORESIST PATTERN USING THE SAME

(71) Applicant: DONGWOO FINE-CHEM CO., LTD., Jeonbuk-do (KR)

(72) Inventors: GI JIN KWUN, Jeonbuk-do (KR); BAEK HYUN CHO, Jeonbuk-do (KR); HYUNG SUB CHOI, Jeonbuk-do (KR)

(21) Appl. No.: 19/576,246

(22) Filed: Mar. 24, 2026

(30) Foreign Application Priority Data
Mar. 25, 2025 (KR) 10-2025-0038338

(51) Int. Cl. C11D 7/50; C11D 7/26; G03F 7/42

(52) U.S. Cl. CPC C11D 7/5022; C11D 7/266; G03F 7/422

(57) ABSTRACT

A cleaning composition includes an alcohol-based solvent, and an alkyl acetate or an alkyl formate. A content of the alcohol-based solvent is 50 wt % or more, and less than 100 wt % based on a total weight of the composition. The cleaning composition provides improved pattern stability and enhanced capability of removing a photoresist residue.

### CROSS-REFERENCE TO RELATED APPLICATION AND CLAIM OF PRIORITY

This application claims the benefit under 35 U.S.C. § 119 of Korean Patent Application No. 10-2025-0038338 filed on Mar. 25, 2025, in the Korean Intellectual Property Office, the entire disclosure of which is incorporated herein by reference for all purposes.

### BACKGROUND

### 1. Field

The present invention relates to a cleaning composition and a method for forming a photoresist pattern using the same.

### 2. Description of the Related Art

A composition containing an alcohol-based solvent can be used for cleaning an electronic device such as a semiconductor device or may be used for removing photoresist residues during a photo-lithography process in a semiconductor device manufacture process.

For example, a photoresist composition may be applied to a semiconductor substrate, and then soft-baked to form a photoresist layer. Subsequently, the photoresist layer may be partially removed by exposure and development processes to form a photoresist pattern. An etching process using the photoresist pattern as an etching mask may be performed to form wirings, electrodes, insulating patterns, or the like, of the semiconductor device.

As described above, the photoresist pattern may be formed by the exposure and development processes, and then photoresist residues on the semiconductor substrate may be removed using a cleaning solution. However, the cleaning solution may damage the photoresist pattern or may cause surface defects of the photoresist pattern.

### SUMMARY

According to an aspect of the present invention, there is provided a cleaning composition providing improved cleaning capability and pattern reliability.

According to an aspect of the present invention, there is provided a method of forming a photoresist pattern using the cleaning composition.

(1) A cleaning composition, including: an alcohol-based solvent; and an alkyl acetate or an alkyl formate, wherein a content of the alcohol-based solvent is 50 wt % or more, and less than 100 wt % based on a total weight of the composition.

(2) The cleaning composition of the above (1), wherein a content of the alkyl acetate or the alkyl formate is in a range from 0.0001 ppm to 10 ppm based on the total weight of the composition.

(3) The cleaning composition of the above (1), wherein an alkyl group contained in the alkyl acetate or the alkyl formate has 2 to 5 carbon atoms.

(4) The cleaning composition of the above (1), wherein the alkyl acetate includes at least one selected from the group consisting of ethyl acetate, propyl acetate, isopropyl acetate, butyl acetate, s-butyl acetate, tert-butyl acetate and pentyl acetate.

(5) The cleaning composition of the above (1), wherein the alkyl formate includes at least one selected from the group consisting of ethyl formate, propyl formate, isopropyl formate, butyl formate and pentyl formate.

(6) The cleaning composition of the above (1), wherein the cleaning composition includes the alkyl acetate and the alkyl formate.

(7) The cleaning composition of the above (1), wherein the alcohol-based solvent includes an alcohol having 2 to 5 carbon atoms.

(8) The cleaning composition of the above (1), wherein the alcohol-based solvent includes at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.

(9) The cleaning composition of the above (1), wherein the alcohol-based solvent includes 2-propanol.

(10) The cleaning composition of the above (9), wherein the alcohol-based solvent further includes at least one selected from the group consisting of ethanol, 1-propanol, 1-butanol and 1-pentanol.

(11) The cleaning composition of the above (1), wherein a boiling point of the alcohol-based solvent is 110° C. or less, and a vapor pressure of the alcohol-based solvent at 25° C. is 0.5 kPa or higher.

(12) The cleaning composition of the above (1), wherein a content of the alcohol-based solvent is 99 wt % or more, and less than 100 wt % based on the total weight of the composition.

(13) A method of forming a photoresist pattern, including: forming a photoresist layer on a substrate; partially removing the photoresist layer to form a photoresist pattern; and cleaning the substrate on which the photoresist pattern is formed using the above-described cleaning composition.

Photoresist residues generated after a development process may be effectively removed using a cleaning composition according to embodiments of the present invention. Further, damages to the photoresist pattern during a cleaning process may be prevented to achieve a uniform pattern profile.

Accordingly, a high-resolution target pattern having desired pattern spacing and size may be stably formed by a photo-lithography process using the photoresist pattern.

### BRIEF DESCRIPTION OF THE DRAWINGS

FIGS. 1 to 4 are schematic cross-sectional views illustrating a method of forming a pattern in accordance with example embodiments.

### DETAILED DESCRIPTION OF THE EMBODIMENTS

Embodiments of the present invention provide a cleaning composition including an alcohol-based solvent, and an alkyl acetate or an alkyl formate. Further, a method of forming a photoresist pattern using the cleaning composition is provided.

The term “ppm” used herein refers to “parts-per-million (10⁻⁶)” and may refer to a weight-based content.

Hereinafter, embodiments of the present invention will be described in detail.

### <Cleaning Composition>

A cleaning composition (hereinafter, that may be abbreviated as a composition) according to example embodiments may include an alcohol-based solvent, and an alkyl acetate or an alkyl formate.

The alcohol-based solvent may remove process residues such as an undeveloped photoresist or a residual developer present on a semiconductor substrate. For example, organic and inorganic residues present between photoresist patterns after exposure and development processes may be effectively removed from the semiconductor substrate using the alcohol-based solvent included in the cleaning composition.

In some embodiments, the alcohol-based solvent may include an alcohol having 2 to 5 carbon atoms.

For example, the alcohol-based solvent may include ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol, 2,2-dimethyl-1-propanol, or the like. These may be used alone or in a combination of two or more therefrom.

For example, methanol has a high volatility to have low cleaning capability and stability. An alcohol having more than 5 carbon atoms may remain on a surface of a semiconductor substrate after cleaning. Thus, when the alcohol-based solvent includes an alcohol having 2 to 5 carbon atoms, defects during a semiconductor device fabrication may be reduced.

In example embodiments, the alcohol-based solvent may be obtained by refining a crude material. A purity of the alcohol-based solvent may be improved by the refining process.

For example, 2-propanol derived from a fossil resource such as coal, oil, natural gas, etc., as a raw material before the refinement may be used as the alcohol-based solvent, and 2-propanol (Bio-2-propanol) derived from a biomass may be used.

Examples of Bio-2-propanol include 2-propanol obtained using bacteria capable of producing 2-propanol from a biomass material (see International Patent Publication No. 2009/008377), 2-propanol obtained by hydrating propylene obtained using a biomethanol, 2-propanol obtained by reducing acetone obtained using bioethanol, 2-propanol obtained by hydrating propylene obtained using bioethanol, or the like.

In some embodiments, the alcohol-based solvent may include a secondary alcohol. Examples of the secondary alcohol include 2-propanol, 2-butanol, 2-pentanol, 3-pentanol, or 3-methyl-2-butanol, preferably may include 2-propanol.

In some embodiments, the alcohol-based solvent may include at least one selected from the group consisting of ethanol, 1-propanol, 2-propanol, 1-butanol and 1-pentanol.

In some embodiments, the alcohol-based solvent may include 2-propanol, and an alcohol-based solvent different from 2-propanol. For example, the alcohol-based solvent may include 2-propanol, and ethanol, 1-propanol, 1-butanol and/or 1-pentanol.

For example, the alcohol having 2 or 3 carbon atoms have a low boiling point, and thus may not remain on a surface of a semiconductor substrate after a cleaning process. Accordingly. a production yield of a semiconductor device may be increased.

In some embodiments, the alcohol-based solvent may include an alcohol having a boiling point of 110° C. or lower. For example, the alcohol having a boiling point of 110° C. or lower may include ethanol, 1-propanol, 2-propanol, 2-butanol, isobutanol, tert-butanol, tert-amyl alcohol, or the like.

For example, the alcohol having a boiling point of 110° C. or lower may be vaporized at a lower temperature, and thus may not remain on the surface of the semiconductor substrate after the cleaning process.

In some embodiments, a vapor pressure of the alcohol-based solvent at 25° C. may be 0.5 kPa or higher. For example, the alcohol having a vapor pressure of 0.5 kPa or higher at 25° C. may include ethanol, 1-propanol, 2-propanol, 1-butanol, 2-butanol, isobutanol, tert-butanol, 2-pentanol, 3-pentanol, tert-amyl alcohol, 2,2-dimethyl-1-propanol, or the like. These may be used alone or in a combination of two or more therefrom.

For example, the alcohol having a vapor pressure of 0.5 kPa or higher at 25° C. may be vaporized more easily, and may not remain on the surface of the semiconductor substrate after the cleaning process.

In example embodiments, a content of the alcohol-based solvent based on a total weight of the composition may be 50 wt % or more and less than 100 wt %, 60 wt % or more and less than 100 wt %, 70 wt % or more and less than 100 wt %, 80 wt % or more and less than 100 wt %, 90 wt % or more and less than 100 wt %, 99 wt % or more and less than 100 wt %, 99.9 wt % or more and less than 100 wt %, 99.95 wt % or more and less than 100 wt %, or 99.99 wt % or more and less than 100 wt %.

In some embodiments, the alcohol-based solvent may include 2-propanol. A content of 2-propanol based on the total weight of the composition may be 99 wt % or more and less than 100 wt %. In an embodiment, the content of 2-propanol based on the total weight of the composition may be 99.9 wt % or more and less than 100 wt %, 99.95 wt % or more and less than 100 wt %, or 99.99 wt % or more and less than 100 wt %.

In some embodiments, the cleaning composition may include an alcohol-based solvent different from 2-propanol, as a remainder excluding the contents of 2-propanol and alkyl acetate/alkyl formate. For example, the cleaning composition may include an alkyl acetate/alkyl formate in an amount described below and 2-propanol in the amount described above, and may include the alcohol-based solvent different from the 2-propanol in a remaining amount.

The term “remainder or remaining amount” as used herein refers to a variable amount that may be changed depending on an addition of another component. For example, the cleaning composition may further include an organic solvent other than the alcohol-based solvent within a range in which the action of the alcohol-based solvent and the alkyl acetate/alkyl formate may not be hindered.

In example embodiments, the cleaning composition may include an alkyl acetate and/or an alkyl formate.

The alkyl acetate and/or the alkyl formate may at least partially dissolve photoresist residues to facilitate cleaning by the alcohol-based solvent. Further, the alkyl acetate and/or the alkyl formate may act as a buffer for the alcohol-based solvent, so that a line-width uniformity of a photoresist pattern during the cleaning process may be enhanced.

In some embodiments, an alkyl group in the alkyl acetate or the alkyl formate may have 2 to 5 carbon atoms. In the carbon number range, sufficient solubility and cleaning capability of the photoresist residues may be provided. Additionally, the photoresist pattern may be prevented from being dissolved by the alkyl acetate or the alkyl formate to cause pattern damage, pattern collapse, etc.

In example embodiments, the alkyl acetate may include ethyl acetate, propyl acetate, isopropyl acetate, butyl acetate, s-butyl acetate, tert-butyl acetate, pentyl acetate, or the like. These may be used alone or in a combination of two or more therefrom.

In example embodiments, the alkyl formate may include ethyl formate, propyl formate, isopropyl formate, butyl formate, pentyl formate, or the like. These may be used alone or in combination of two or more therefrom.

In some embodiments, the cleaning composition may include both the alkyl acetate and the alkyl formate. In this case, the cleaning capability of the photoresist residues may be increased, and the line-width uniformity of the photoresist pattern may be further improved after the cleaning process using the cleaning composition.

In example embodiments, a content of the alkyl acetate or alkyl formate may be in a range from 0.0001 ppm to 10 ppm based on the total weight of the cleaning composition. Preferably, the content of the alkyl acetate or alkyl formate may be 0.001 ppm or more and less than 10 ppm, from 0.001 ppm to 5 ppm, or from 0.01 ppm to 5 ppm based on the total weight of the composition.

In the content range, sufficient dissolving capability of the photoresist residues by the alkyl acetate or the alkyl formate may be provided. Further, damages to the photoresist pattern due to an excessive content of the alkyl acetate or alkyl formate may be prevented.

In some embodiments, the alkyl acetate or alkyl formate may be added as a separate additive to the alcohol-based solvent to prepare the cleaning composition.

In some embodiments, the alkyl acetate or the alkyl formate may be prepared through a conversion reaction of an alcohol during preparation of the alcohol-based solvent. For example, the alkyl acetate or alkyl formate may be generated by converting a by-product such as a ketone contained in the alcohol-based solvent. In an embodiment, the ketone may be converted into an acid in the alcohol-based solvent, and then reacted with the alcohol to produce the alkyl acetate or the alkyl formate.

### <Method of Forming Photoresist Pattern>

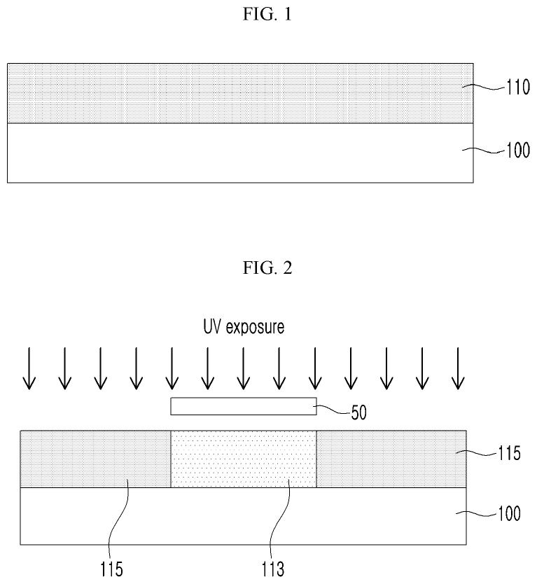

FIGS. 1 to 4 are schematic cross-sectional views for describing a method of forming a pattern according to embodiments. For example, in FIGS. 1 to 4, a method of forming a pattern using a negative photoresist is provided.

However, the cleaning composition according to embodiments is not limited to the processes of FIGS. 1 to 4, and may also be used in a pattern formation process using a positive photoresist.

Referring to FIG. 1, a photoresist layer 110 may be formed by coating a photoresist material on a substrate 100.

The substrate 100 may include a semiconductor material such as single crystal silicon or single crystal germanium. The substrate 100 may be formed to include polysilicon.

In some embodiments, a soft baking process may be performed after forming the photoresist layer 110. Accordingly, an organic solvent included in the photoresist layer 110 may be evaporated.

Referring to FIG. 2, an non-exposed portion 113 and an exposed portion 115 may be formed on the substrate 100 by an exposure process. The exposure process may be performed using a light source (e.g., a UV light source such as an EUV light source, a KrF laser, etc.) and an exposure mask 50.

Light passing through the exposure mask 50 may be irradiated to the photoresist layer 110. Accordingly, the photoresist layer 110 may have the non-exposed portion 113 and the exposed portion 115.

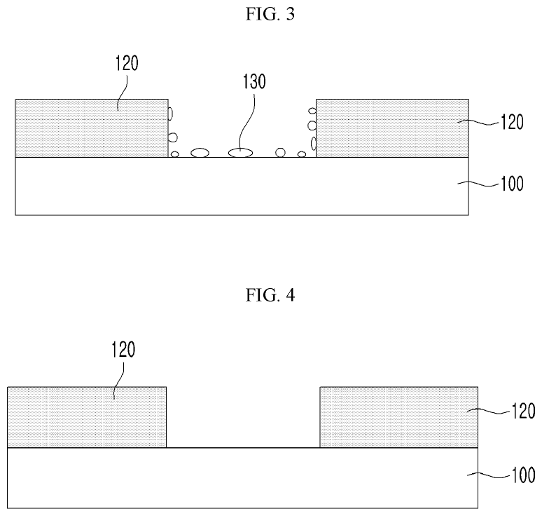

Referring to FIG. 3, a photoresist pattern 120 may be formed on the substrate 100 by a developing process. For example, the non-exposed portion 113 may be removed from the substrate 100 using a developer solution to form the photoresist pattern 120 including the exposed portion 115. The developer solution may be an aqueous tetramethylammonium hydroxide (TMAH) solution.

FIG. 3 illustrates a pattern formation process using a negative photoresist, but the pattern formation is not limited thereto. For example, the pattern formation process may be performed using a positive photoresist. In this case, the exposed portion 115 may be removed, and a photoresist pattern may be formed from the non-exposed portion 113.

In some embodiments, a post-baking process may be further performed after the exposure process or after the development process.

A developing residue 130 may be present on the substrate 100 after the developing process. The developing residue 130 may be an undeveloped photoresist or a developing solution residue. When the developing residue 130 remains on the substrate 100 or the photoresist pattern 120, defects may occur during a fabrication of a semiconductor device.

Referring to FIG. 4, the above-described cleaning composition according to embodiments may be applied or immersed on the substrate 100. Accordingly, the developing residue 130 formed on the substrate 100 or the photoresist pattern 120 may be removed.

The cleaning process may be performed by applying the cleaning composition according to the above-described embodiments described to the substrate 100 under commonly known cleaning conditions.

In some embodiments, a cleaning temperature may be in a range from 25° C. to 70° C., preferably from 25° C. to 50° C. A residence time of the substrate 100 when immersed in the cleaning composition may be in a range from about 5 seconds to 10 minutes, preferably from 10 seconds to 5 minutes.

In some embodiments, in the cleaning process, a first cleaning of removing the developing residue using deionized water may be performed, and then a second cleaning using the cleaning composition according to the above-described embodiments may be performed.

As described above, the cleaning composition includes an alcohol-based solvent and the alkyl acetate/alkyl formate, so that surface damages and pattern collapse of the photoresist pattern 120 may be prevented, and the developing residue 130 may be effectively removed. Accordingly, resolution and reliability of the photo-lithography process using the photoresist pattern 120 may be improved, and a target pattern with a fine line width may be obtained.

In addition to the pattern formation process using a photoresist, the cleaning composition according to embodiments may be used for cleaning an electronic device such as a semiconductor or a display, and may also be used for manufacturing various devices (an electric device such as a touch sensor, a display device, etc.) in which the cleaning process is performed.

Hereinafter, preferred embodiments are provided to help understanding of the present invention, but these embodiments are merely illustrative of the present invention and do not limit the scope of the attached patent claims, and it is obvious to those skilled in the art that various changes and modifications to the embodiments are possible within the scope of the present invention. These modifications are to be interpreted as being within the scope of the attached claims.

### Experimental Example

The cleaning compositions of Examples and Comparative Examples were prepared by mixing components with corresponding contents shown in Table 1 below. The content of each component is expressed based on a total weight of the cleaning composition.

### (1) Formation of Photoresist Pattern

A bottom anti-reflection coating composition (DUV42P-6, Nissan Chemical Industries) was spin-coated on a silicon substrate, and then heated at 215° C. for 90 seconds to form an anti-reflection coating having a thickness of 600 Å. A polyhydroxystyrene (PHS)-type photoresist (KTF-5664, Dongwoo Fine-Chem) was spin-coated on the anti-reflection coating, and then a soft-baking was performed in an oven at 100° C. for 60 seconds to form a photoresist layer. The photoresist layer was exposed using a scanner equipped with a KrF laser, and a post-baking was performed in an oven at 110° C. for 60 seconds.

A silicon substrate including an exposed photoresist layer was developed by immersing the substrate in a 2.38 wt % tetramethylammonium hydroxide (TMAH) aqueous solution for 60 seconds to form a photoresist pattern, and then deionized water was used to remove development residues. Thereafter, 30 mL of the cleaning compositions of Examples and Comparative Examples prepared according to Table 1 were applied on the surface of the silicon substrate for 10 seconds, and then the wafer was dried by high-speed spinning to form a photoresist pattern having a line and space (L/S) of 180 nm.

### (2) Evaluation on Pattern Collapse

The photoresist pattern was observed using a CD-SEM (Hitachi), and a pattern collapse was evaluated according to the following criteria.
o: No pattern collapse observed
Δ: Pattern collapse occurred only in a pattern at a periphery of the substrate
X: Pattern collapse occurred at a periphery and a center of the substrate

### (3) Evaluation on Line-Width Uniformity

Maximum and minimum widths of the photoresist pattern were measured using a CD-SEM (Hitachi), and a difference between the maximum and minimum widths was calculated.

### (4) Evaluation on Photoresist Pattern Damage

A difference in photoresist thickness before and after the treatment by the cleaning composition was measured using an FE-SEM (Hitachi), and a photoresist damage (thickness reduction) was evaluated as follows.
o: Photoresist thickness reduction of 20 Å or less
Δ: Photoresist thickness reduction greater than 20 Å, and 50 Å or less
X: Photoresist thickness reduction greater than 50 Å

The evaluation results are shown in Table 1 below.

TABLE 1

| | alkyl acetate/ | | | | | | |
|---|---|---|---|---|---|---|---|
| | alkyl formate | | alcohol-based | | | Line-width | |
| | | content | solvent | | pattern | Uniformity | pattern |
| | type | (ppm) | type | content | collapse | (nm) | damage |
| Example 1 | A3 | 0.0001 | B1 | remainder | ◯ | 4.1 | ◯ |
| Example 2 | A3 | 0.001 | B1 | remainder | ◯ | 2.7 | ◯ |
| Example 3 | A3 | 1 | B1 | remainder | ◯ | 2.8 | ◯ |
| Example 4 | A3 | 5 | B1 | remainder | ◯ | 2.3 | ◯ |
| Example 5 | A3 | 10 | B1 | remainder | ◯ | 3.2 | Δ |
| Example 6 | A3 | 15 | B1 | remainder | ◯ | 4.3 | Δ |
| Example 7 | A1 | 5 | B1 | remainder | ◯ | 3.8 | ◯ |
| Example 8 | A2 | 5 | B1 | remainder | ◯ | 2.4 | ◯ |
| Example 9 | A4 | 5 | B1 | remainder | ◯ | 2.6 | ◯ |
| Example 10 | A5 | 5 | B1 | remainder | ◯ | 3.2 | ◯ |
| Example 11 | A6 | 5 | B1 | remainder | ◯ | 2.5 | ◯ |
| Example 12 | A7 | 5 | B1 | remainder | ◯ | 2.4 | ◯ |
| Example 13 | A2 | 5 | B2 | remainder | ◯ | 2.7 | ◯ |
| Example 14 | A2 | 5 | B3 | remainder | ◯ | 2.8 | ◯ |
| Example 15 | A2 | 5 | B4 | remainder | ◯ | 2.5 | ◯ |
| Example 16 | A2 | 5 | B5 | remainder | ◯ | 2.8 | ◯ |
| Example 17 | A2 | 5 | B6 | remainder | ◯ | 3.0 | Δ |
| Example 18 | A2 | 5 | B7 | remainder | ◯ | 2.9 | Δ |
| Example 19 | A4 | 5 | B1 | 50 wt % | ◯ | 2.8 | ◯ |
| | | | B2 | remainer | | | |
| Example 20 | A4 | 5 | B1 | 50 wt % | ◯ | 2.5 | ◯ |
| | | | B3 | remainer | | | |
| Example 21 | A4 | 5 | B2 | 50 wt % | ◯ | 2.7 | ◯ |
| | | | B3 | remainer | | | |
| Example 22 | A3 | 2.5 | B1 | remainder | ◯ | 2.3 | ◯ |
| | A6 | 2.5 | | | | | |
| Example 23 | A2 | 0.00008 | B1 | remainder | ◯ | 4.5 | ◯ |
| Comparative | — | — | — | (100 wt %) | X | 6.7 | ◯ |
| Example 1 | | | (water) | | | | |
| Comparative | A3 | 5 | — | (remainder) | X | 6.6 | ◯ |
| Example 2 | | | (water) | | | | |
| Comparative | — | — | B1 | 100 wt % | ◯ | 5.5 | ◯ |
| Example 3 | | | | | | | |
| Comparative | — | — | B1 | 50 wt % | ◯ | 5.4 | ◯ |
| Example 4 | | | B2 | 50 wt % | | | |
| Comparative | A8 | — | B1 | remainder | Δ | 3.7 | Δ |
| Example 5 | | | | | | | |
| Comparative | A9 | — | B1 | remainder | Δ | 3.5 | v |
| Example 6 | | | | | | | |

The components shown in Table 1 are as follows.
A1: methyl acetate
A2: ethyl acetate
A3: isopropyl acetate
A4: pentyl acetate
A5: hexyl acetate
A6: propyl formate
A7: butyl formate
A8: ethyl propionate
A9: ethyl butyrate
B1: 2-propanol
B2: 1-propanol
B3: ethanol
B4: 1-butanol
B5: 1-pentanol
B6: 1-heptanol
B7: 1-hexanol

Referring to Table 1, the cleaning compositions of Examples containing the alcohol-based solvent and the alkyl acetate/alkyl formate were used to prevent the photoresist pattern collapse and damage while achieving the improved line-width uniformity.

In Comparative Examples 1 and 2 where the cleaning solution composition containing water instead of the alcohol-based solvent was used, the pattern collapse occurred and the line-width uniformity was significantly deteriorated.

In Comparative Examples 3 and 4 where the alkyl acetate/alkyl formate was omitted, the line-width uniformity was deteriorated compared to those of Examples.

In Comparative Examples 5 and 6 where propionate or butyrate was used, the pattern reliability and line-width uniformity were overall lower than those of Examples.

Referring to Examples 5 and 6, the content of the alkyl acetate/alkyl formate was slightly increased, and the line-width uniformity was relatively lowered and the pattern damage was relatively increased.

Referring to Example 23, the content of the alkyl acetate/alkyl formate was slightly lowered, the photoresist residue was not sufficiently removed to lower the line-width uniformity.

Referring to Example 10, an acetate containing an alkyl group having 6 carbon atoms was used to provide relatively reduced line-width uniformity and relatively increased pattern damage.

Referring to Examples 17 and 18, an alcohol-based solvent having carbon atoms greater than 5 was used to relatively increase the pattern damage.

Referring to Example 22, the combination of the alkyl acetate and the alkyl formate was used to provide further improved pattern properties.

What is claimed is:

1. A cleaning composition, comprising:
an alcohol-based solvent; and
an alkyl acetate or an alkyl formate,
wherein a content of the alcohol-based solvent is 50 wt % or more, and less than 100 wt % based on a total weight of the composition.

2. The cleaning composition of claim 1, wherein a content of the alkyl acetate or the alkyl formate is in a range from 0.0001 ppm to 10 ppm based on the total weight of the composition.

3. The cleaning composition of claim 1, wherein an alkyl group contained in the alkyl acetate or the alkyl formate has 2 to 5 carbon atoms.

4. The cleaning composition of claim 1, wherein the alkyl acetate includes at least one selected from the group consisting of ethyl acetate, propyl acetate, isopropyl acetate, butyl acetate, s-butyl acetate, tert-butyl acetate and pentyl acetate.

5. The cleaning composition of claim 1, wherein the alkyl formate includes at least one selected from the group consisting of ethyl formate, propyl formate, isopropyl formate, butyl formate and pentyl formate.

6. The cleaning composition of claim 1, wherein the cleaning composition includes the alkyl acetate and the alkyl formate.

7. The cleaning composition of claim 1, wherein the alcohol-based solvent includes an alcohol having 2 to 5 carbon atoms.

8. The cleaning composition of claim 1, wherein the alcohol-based solvent includes at least one selected from the group consisting of ethanol, 1-propanol, 2-propanol, 1-butanol, 2-butanol, isobutanol, tert-butanol, 1-pentanol, 2-pentanol, 3-pentanol, 2-methyl-1-butanol, tert-amyl alcohol, 3-methyl-2-butanol, 3-methyl-1-butanol and 2,2-dimethyl-1-propanol.

9. The cleaning composition of claim 1, wherein the alcohol-based solvent includes 2-propanol.

10. The cleaning composition of claim 9, wherein the alcohol-based solvent further comprises at least one selected from the group consisting of ethanol, 1-propanol, 1-butanol and 1-pentanol.

11. The cleaning composition of claim 1, wherein a boiling point of the alcohol-based solvent is 110° C. or less, and a vapor pressure of the alcohol-based solvent at 25° C. is 0.5 kPa or higher.

12. The cleaning composition of claim 1, wherein a content of the alcohol-based solvent is 99 wt % or more, and less than 100 wt % based on the total weight of the composition.

13. A method of forming a photoresist pattern, comprising:
forming a photoresist layer on a substrate;
partially removing the photoresist layer to form a photoresist pattern; and
cleaning the substrate on which the photoresist pattern is formed using the cleaning composition of claim 1.
